(19) United States
(12) Patent Application Publication
(10) Pub. No.: US 2008/0267418 A1
(43) Pub. Date: Oct. 30, 2008

(54) Method and apparatus for dynamically adjusting the spectral content of an audio signal

(75) Inventors: J. Craig Oxford, Nashville, TN (US); D. Michael Shields, St. Paul, MN (US)

Correspondence Address: W. EDWARD RAMAGE, COMMERCE CENTER SUITE 1000, 211 COMMERCE ST, NASHVILLE, TN, 37201, US

(73) Assignee: Iroquois Holding Company

(21) Appl. No.: 11/633,908

(22) Filed: Dec. 5, 2006

Related U.S. Application Data
(60) Provisional application No. 60/794,293, filed on Apr. 22, 2006.

(51) Int. Cl. H03G 3/00

(52) U.S. Cl. 381/61

(57) ABSTRACT

The present invention involves a method for dynamically adjusting the spectral content of an audio signal, which increases the harmonic content through the systematic introduction of amplitude asymmetry. The present invention also involves an apparatus for dynamically adjusting the spectral content of an audio signal which consists of a constant current source, an input buffer amplifier, an output buffer amplifier and a progressively biased system of bipolar junctions, which will produce a controlled asymmetry of the transfer characteristic.

This application claims the benefit of provisional patent application Ser. No. 60/794,293, filed Apr. 22, 2006 by the present inventors.

### BACKGROUND OF THE INVENTION

1. Field of Invention

The reproduction of music recordings is typically performed by a chain of equipment consisting of at least a playback device for the type of recording at hand, an amplifier and a loudspeaker.

There is abundant anecdotal evidence that many listeners prefer that the music reproduction chain should include a vacuum tube based amplifier, which should also be preferably single-ended (as opposed to push-pull). Other factors being equal, the performance of such an amplifier will be objectively inferior to almost any other commonly used vacuum-tube or solid-state push-pull or topologically symmetrical amplifier.

The stated subjective preference nevertheless remains. It is important to understand why this might be so. In the production of music whether by electric guitar or symphony orchestra, preferences about musical instruments are influenced by the harmonic structure of the sound, which they produce. This is a very fundamental aspect of timbre. Some orchestras will even limit the acceptable historical provenance of musicians' instruments based on the tonal qualities associated with particular periods of manufacture. This importance of harmonic structure pertains equally to reproduced music. The reproduction of music is certainly not the same thing as its original production and it might be hoped that in the ideal case the reproducing process would be merely a transparent vessel for the original sounds. Alas, this is not the case nor is it likely to be so in the foreseeable future. Refinement of the measured performance of reproducing equipment is not always accompanied by an audible result, which is musically convincing. There are many reasons why this might be the case. Some of these are discussed below having particular relevance to the harmonic structure of the reproduced sound.

The objective inferiority of the single-ended vacuum-tube amplifier takes the form of higher numerical distortion. Measured as undesired harmonic content such an amplifier will exhibit a total harmonic distortion, THD, typically many times that of a symmetrical or push-pull amplifier. It should be pointed out that THD is a single-number expression, which does not quantify the spectral content of the distortion. Harmonic distortion consists of additions to the fundamental tone at new frequencies, which are integral multiples of the tone. For example an input signal to an amplifier at 1 kHz will result in an output signal which contains the original 1 kHz tone plus smaller amounts of 2,3,4 etc. kHz, as shown in FIG. 1. The THD is simply the square root of the sum of the squares of the harmonic amplitudes divided by the total amplitude. Multiplied by 100, the THD is usually stated in percent.

The use of this single-number rating provides a coarsely useful figure of merit for an amplifier but it may be seriously misleading because it does not qualitatively describe the distortion. Evidence of this is the often-stated listener preference for amplifiers with higher THD. Push-pull or symmetrical amplifiers are an example of this difficulty. The THD is reduced in these amplifiers because the topological symmetry causes the evenorder harmonies (2^{nd}, 4^{th} etc.) to be cancelled. This results in an “empty” harmonic spectrum in which only the odd-order harmonics (3^{rd}, 5^{th} etc.) are present as shown in FIG. 2. In musical terms, the even harmonics are “consonant” and the odd harmonics are “dissonant.” Since in practical amplifiers the distortion is never zero, it would be better if the unavoidable residual distortion could be consonant rather than dissonant.

It is a further characteristic of amplifiers generally that the onset of whatever distortion occurs is progressive with signal amplitude. Extremely “clean” amplifiers may show very little distortion until they closely approach overload at which point the distortion increases almost catastrophically. Single-ended vacuum-tube amplifiers on the other hand have a very progressive distortion characteristic with signal amplitude. Pushpull vacuum-tube amplifiers are somewhere in between. Often this is related to the use of negative feedback, which is generally less in vacuum-tube designs and more in solid-state designs. The difference is illustrated in FIG. 3.

Another aspect of amplifiers, which affects the structure of the distortion, is the use of negative feedback. The application of negative feedback reduces the measured distortion in any amplifier. In practice, the reduction of distortion components by applying feedback does not uniformly reduce these components. The low-order, i.e. 2^{nd} and 3^{rd} harmonics will be reduced more effectively than the higher order harmonics. The consequence is that even though the THD is reduced the remaining distortion spectrum consists mainly of high order harmonics. This type of distortion is particularly unpleasant because it is spectrally far removed from the stimulus and therefore not masked by it. The confluence of subjectively disagreeable results occurs when symmetrical circuits are combined with large amounts of negative feedback. What results is a distortion spectrum, which consists almost entirely of odd high-order products as shown in FIG. 4. Perversely, these circuits usually produce the lowest measured THD.

There are several problems, which can be identified from the foregoing discussion. First, the use of vacuum tubes in modern equipment is undesirable if for no other reason than that reliable sources of supply do not exist. Second, the use of single-ended topologies in amplifiers, which must provide significant power output, is a tremendous disadvantage because of the necessity to operate such a circuit in class A bias. This condition of operation is unacceptably inefficient from both an environmental and engineering perspective. Third, the avoidance of negative feedback in a power amplifier results in a high source impedance of the output, which is contrary to the design requirements of most loudspeaker systems, which will be driven by the amplifier.

An optimum solution for the listener who expresses a preference for the singleended vacuum tube amplifier “sound” as noted above could consist of two parts. First, a power amplifier which can employ moderate feedback to control the output impedance and which is of high enough power capability that the abrupt onset of overload is seldom or never reached in practical operation and second, a signal processing device which introduces a controlled distortion spectrum which arises progressively with amplitude and is monotonic with frequency. Monotonicity in this context means that each higher order of distortion has smaller amplitude, so that the 2^{nd}, 3^{rd}, 4^{th} etc. harmonies become smaller in the same sequence. Such an arrangement can combine the audible attributes, which are sought along with the practical attributes of modern circuitry such as efficiency, adequate power output and longevity.

2. Prior Art

It should be pointed out that in the electric musical instrument industry as well as the recording industry there have been numerous attempts to emulate “tube” sound with solid-state circuits. A review of these attempts shows that they generally seem to misunderstand what they are trying to emulate. They mostly concern themselves with the notion of “soft clipping” in an attempt to render the overload behavior of high-feedback solid-state circuits less abrupt. But this approach only indirectly addresses the question of harmonic structure. Most of the prior art along these lines generally processes the signal symmetrically giving rise mainly to odd harmonics. Also, the processing usually takes the form of inverse-parallel diodes either acting as direct shunt elements across the signal path or as series elements in a feedback loop. The use of symmetrical clipping inside a feedback loop is directly contraindicated in view of the discussion above. Furthermore the use of only one or two diodes across their exponential “knee” makes the action too abrupt to approach the more gradual onset of distortion illustrated in the upper curve of FIG. 3.

Most of the prior art is implemented in a manner, which requires user adjustment of the operating parameters. The present invention can certainly be adjusted as will be shown, but properly implemented it is not necessary. Hard or soft clipping lie outside the intended region of operation although they are considered and provided for. Assuming the voltage gain of the downstream amplifier is known, the operation of the circuit can be coordinated with the overload point of the amplifier so as to optimize the interaction without further adjustment. Much of the need for adjustability in the prior art circuits is because of a narrow operating range and because they are intended as timbral special effects in the production as opposed to the reproduction of music.

At the time of this writing, much audio is stored, distributed and processed in the digital domain. Regardless of this fact, the audio must ultimately be converted back to analog in order to be used. Many audio purists resist the digitization of audio, preferring pure analog sources such as LP recordings, which originate from analog master tapes. Whether the original source is analog or digital, it will at the point of consumption need to be analog. The invention at hand operates entirely in the analog domain. Contemporary technologists might challenge this, asserting that it would be easier and cheaper to perform the desired processing as digital signal processing, DSP. The analog approach is to be preferred because a) the signal might have never existed in digital form and it seems pointless to digitize the signal in order to process it and then have to re-convert to analog, b) the direct analog implementations to be discussed below are low cost, c) the processes involved are dynamically nonlinear and therefore difficult to model in DSP and d) the conversions to and from the digital domain are imperfect processes which should not be included if they are not required. As the state of the art advances it is probable that DSP may become a preferable implementation, in which event, the performance objectives would be unchanged.

### BRIEF DESCRIPTION OF THE INVENTION

The present invention seeks to restore the perceptual and emotional elements lost to technical processes. The present invention is an electronic circuit, which can be arranged to process an audio signal so as to introduce a predictable and controllable harmonic distortion, which is negligible at small signal amplitudes and increases progressively at larger signal amplitudes. Further, no negative feedback is present in the signal path of this processor and the distortion spectrum is monotonic with frequency. In addition, it is possible to protect the downstream amplifier by introducing symmetrical clipping as a minor circuit enhancement to one of the embodiments.

Recent developments in power amplifier technology have resulted in the availability of very high performance Class-D amplifiers, which operate with high efficiency and very low residual distortion. It is contemplated that an optimum use of the signal process to be described may be in conjunction with such Class-D amplifiers as well as the usual types of linear continuous-time amplifiers.

### BRIEF DESCRIPTION OF THE DRAWINGS

FIG. 1 shows a graph of an exemplary output signal.

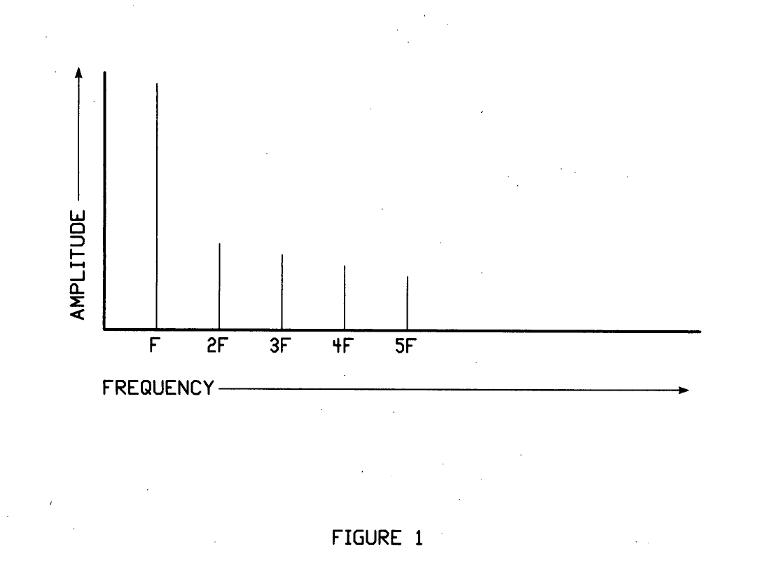

FIG. 2 shows a graph of an exemplary odd-order harmonic spectrum output signal.

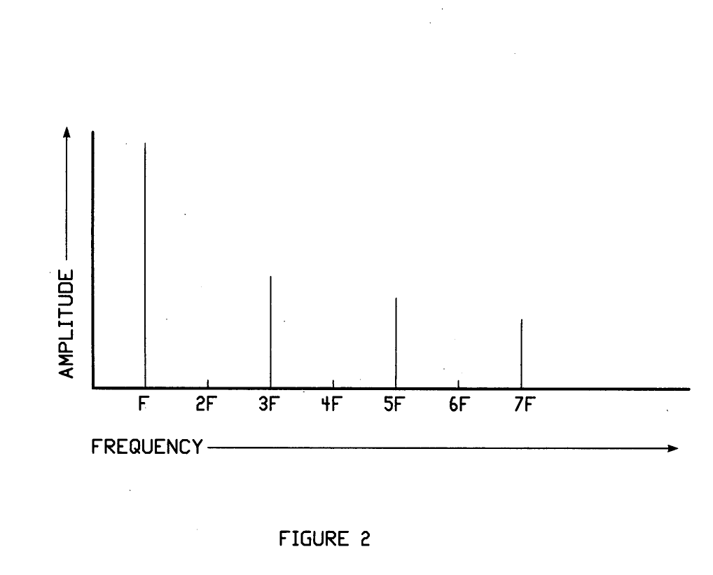

FIG. 3 shows an exemplary graph of total harmonic distortion vs. power output for different amplifiers.

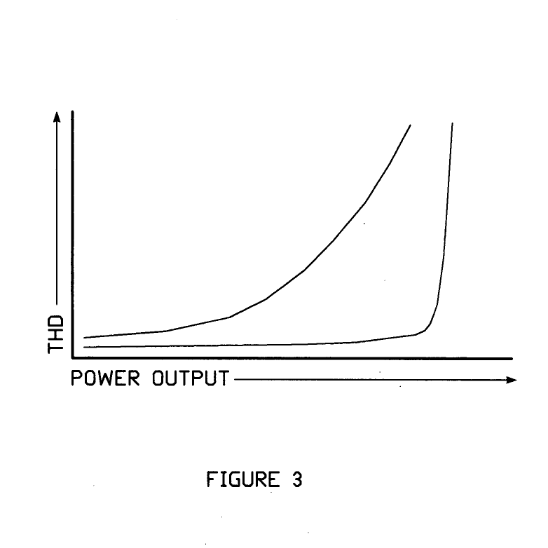

FIG. 4 shows a graph of an exemplary output signal with high-order products.

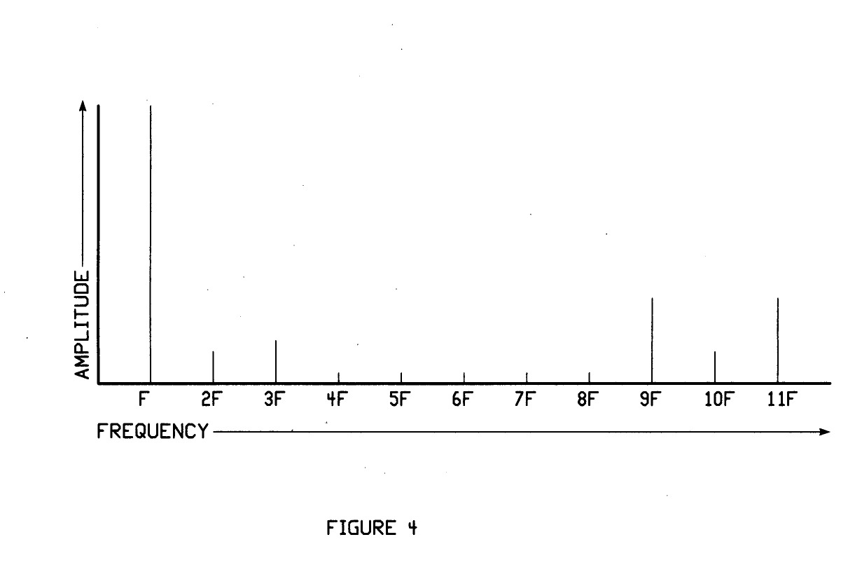

FIG. 5 shows an example of a circuit comprising an input buffer, output buffer, a constant-current source, and a non-linear element.

FIG. 6 shows a diagram of an example of a constant current source.

FIG. 7 shows a diagram of an example of an input buffer.

FIG. 8 shows a diagram of examples of an output buffer.

FIG. 9 shows a diagram of an example of a non-linear element comprising a diode string.

FIG. 10 shows a diagram of an example of a diode string with symmetrical clipping.

### DETAILED DESCRIPTION OF THE INVENTION

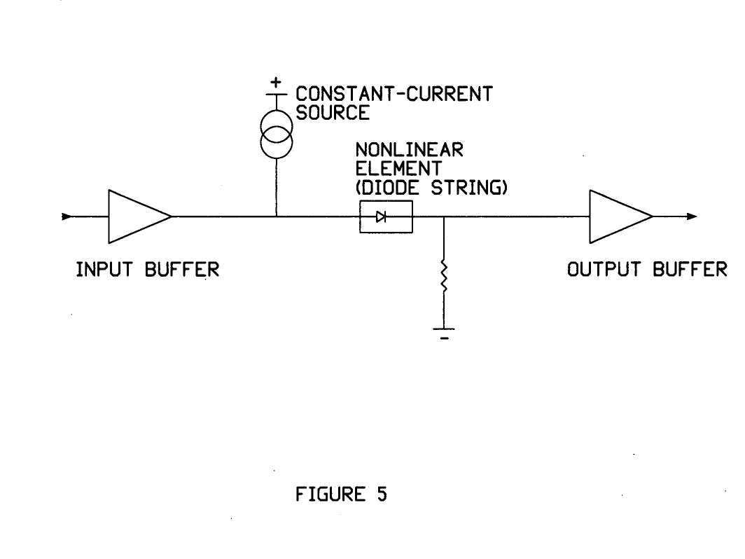

FIG. 5: The basic circuit consists of an input buffer, an output buffer, a constant-current source and a nonlinear element, which may consist of semiconductors in the form of a progressively biased diode string. The audio signal is AC-coupled at both ends of the nonlinear element and it is forward-biased by the constant-current source.

The circuit is intentionally unsymmetrical. As the audio signal voltage goes positive the diode conduction is increased due to increased instantaneous forward bias. As the audio signal voltage goes negative the diode conduction is decreased because the current from the constant-current bias source is sunk by the audio signal. In the limit when the audio signal swings far enough negative, the diode string will become reverse-biased and the output will clip on the negative half-cycles. As long as clipping is avoided, this asymmetry causes the generation of a monotonic harmonic spectrum.

The progressive bias of the diode string and the use of numerous diodes cause the asymmetry to progress over a wide range of voltage. The result might be described as an “elastic” diode.

The individual elements of the circuit can take various forms.

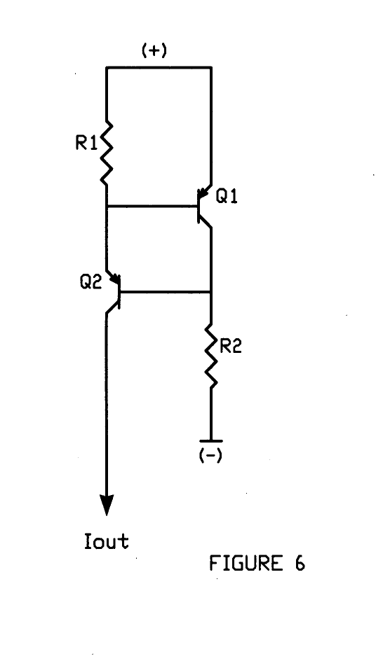

FIG. 6: The constant current source in a preferred embodiment is a ring source. Other topologies such as a Widlar current mirror can also be used. The influence of the current source on the circuit operation has been investigated and the ring source has been found to be optimum when implemented with transistors of high beta. This is because it maintains very high AC impedance over the required frequency range and over the voltage range for which the rest of the circuit is useful. The current value, which is supplied by the constant-current source, is a basic operating parameter of the circuit. For a given range of signal amplitudes, the onset and quantity of harmonic distortion, which is generated, can be adjusted by varying the bias current from the constant-current source.

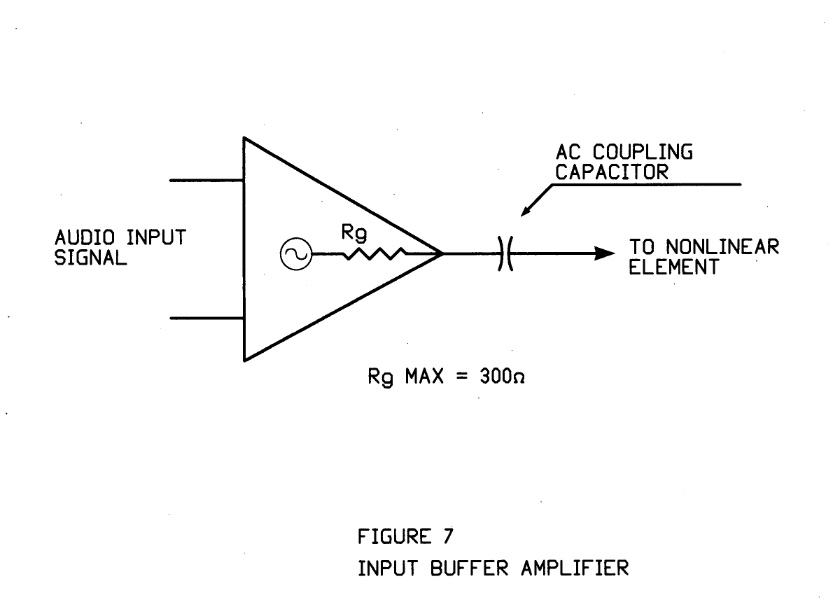

FIG. 7: The input buffer. This stage is required in order to define the source impedance, which drives the diode string. Because the operation is based upon an instantaneous signal-dependent conductance change in the diode string, it follows that if the source resistance is too high the desired nonlinearity will be proportionally less and the intended circuit function will be diminished. In a preferred embodiment a source resistance of up to 300 Ohms has minimal adverse effect on the function. If a driving amplifier with sufficiently low source impedance is available then the input buffer could be replaced with a series resistor. The output of the buffer must be AC-coupled to the input of the diode string with the coupling capacitor value large enough to prevent restriction of low frequencies due to the input impedance of the diode string. The exact value of the input impedance of the diode string depends on the bias current supplied from the constant-current source. Anyone skilled in the art of circuit design will have no difficulty determining the coupling capacitor value.

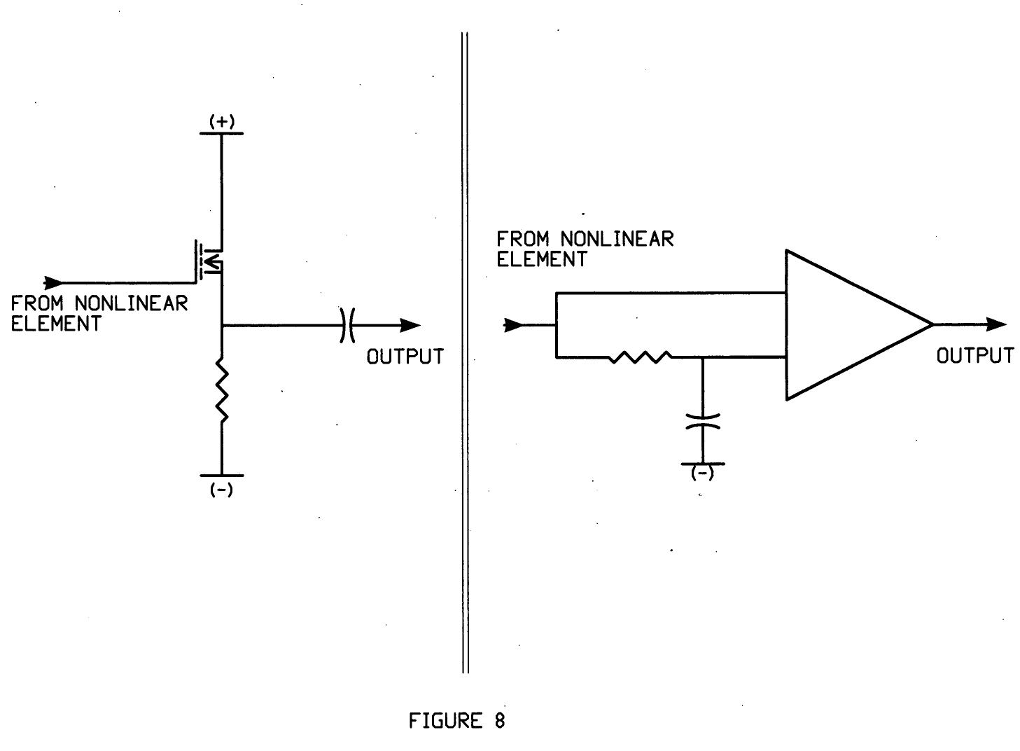

FIG. 8: The output buffer. This stage is required in order to prevent the downstream circuit from placing an undefined load on the diode string. In a preferred embodiment as shown, the buffer is a simple MOSFET source-follower, which is DC-coupled to the output of the diode string. Since the buffer will have a standing DC voltage on its source terminal it may be necessary to AC couple from the buffer to the following circuitry.

In an alternative implementation of the output buffer the signal may be returned to a ground-centered voltage by integrating the DC voltage at the output of the diode string at a sub-audio rate and subtracting it from the signal in a differential amplifier. Both embodiments are shown.

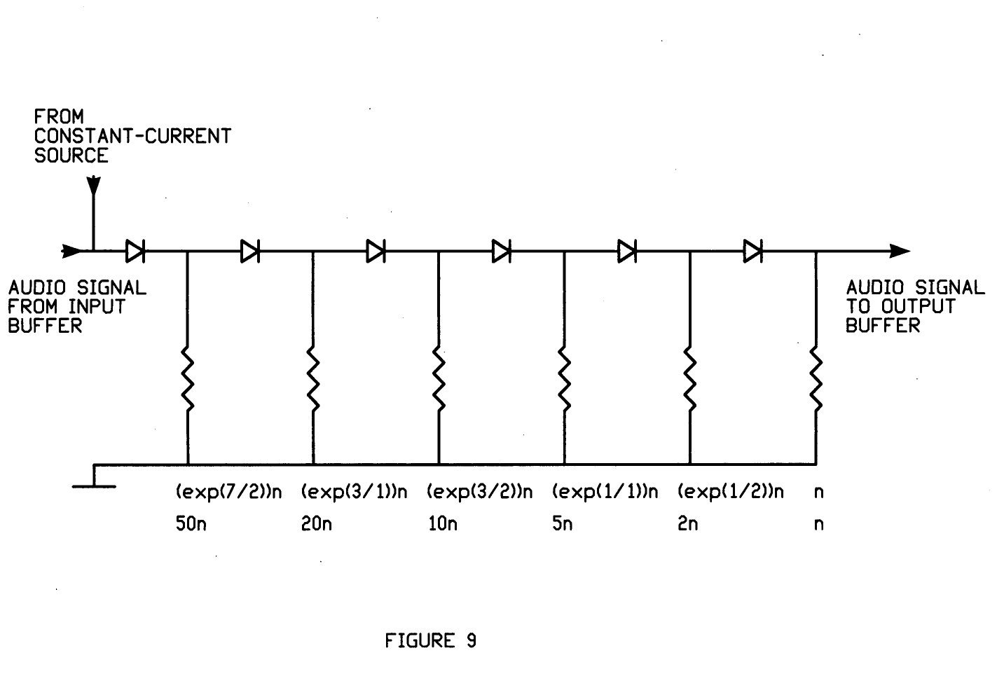

FIG. 9: The diode string. This is the essential element of the circuit. It is where the desired harmonic distortion characteristic is produced. It is a string of diodes connected in series with a bias resistor from each junction in the series string to ground. The resistors progressively load the diode string. In a preferred embodiment they may usefully be in a logarithmic sequence such as 1,2,5 or 1, 3.16, 10 etc with the higher values in the sequence being toward the input end of the string as shown in FIG. 9. The values chosen and the bias current will establish the range of signal voltage and current over which the circuit is useful. The input of the diode string is fed from the constant-current bias source and from the AC-coupled audio input signal from the input buffer. The length of the diode string, i.e. the number of diodes, is somewhat arbitrary. In the embodiment shown six diodes are used, but varying this number or the bias-current ratios does not change the intent of the design.

The diodes may be either explicit diodes or the base-emitter or base-collector diodes of bipolar transistors of either polarity. The junction characteristics of the diodes will affect the choice of bias resistor sequence, the required bias current and the allowable signal range. All these parameters are left to one skilled the art to determine based upon the requirements of the application. Other semiconductor devices, specifically junction field-effect transistors, or JFETs, and metal oxide semiconductor field-effect transistors, or MOSFETs can be similarly applied.

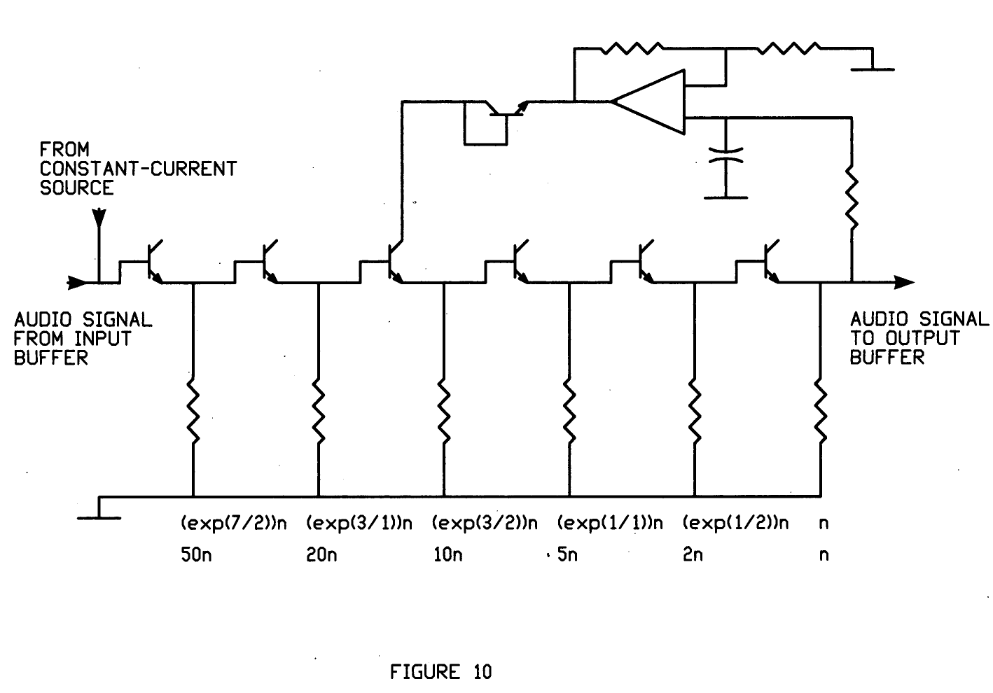

FIG. 10: Symmetrical clipping. This can be a useful addition to the circuit. This addition is not necessary to accomplish the basic desired circuit functions as outlined above. For the embodiment shown the circuit will inherently clip negative half-cycles when the input amplitude swings sufficiently negative to cause the diode string to become reverse-biased. No corresponding mechanism is present to limit the positive signal swing. It can be easily arranged by integrating and buffering the average voltage at the output end of the diode string (Vout, avg) and multiplying it by 2. In this embodiment the diodes are implemented as base-emitter junctions of NPN bipolar transistors. An additional diode connects the collector of a chosen transistor in the string to 2 (Vout, avg). This arrangement will cause the positive peaks to clip at about the same swing as the negative peaks. It should be pointed out that the entire circuit can be implemented in opposite polarity without in any way circumventing the intent of the design.

The operation of the diode string has significant temperature dependency due to the large number of uncompensated semiconductor junctions. As a result of this the circuit should be maintained at constant temperature. This can be done by resistive heating controlled by a simple servo to maintain the temperature within a reasonable band of 10-15 degrees Celsius around a convenient average value. If the implementation is very compact, or better yet monolithic, then very little energy will be required to accomplish this.

1. A method for dynamically adjusting the spectral content of an audio signal, which increases the harmonic content through the systematic introduction of amplitude asymmetry.

2. The method of claim 1 wherein said amplitude asymmetry creates both even and odd order harmonics.

3. The method of claim 1 wherein said asymmetry is controlled so that the resulting harmonic spectrum is low-order and monotonic.

4. An electronic circuit for dynamically adjusting the spectral content of an audio signal comprising
a. A constant current source;
b. An input buffer amplifier,
c. An output buffer amplifier;
d. A progressively biased system of bipolar junctions, which will produce a controlled asymmetry of the transfer characteristic.

5. The electronic circuit as set forth in claim 4 wherein said constant current source is adjustable.

6. (canceled)

7. The electronic circuit as set forth in claim 4 wherein said output buffer amplifier is offset to eliminate the DC offset of the progressively biased semiconductor junction system.

8. The electronic circuit as set forth in claim 4 wherein said output buffer amplifier may be eliminated if the input impedance of the receiving circuit is high.

9. The electronic circuit as set forth in claim 4 incorporated as an integral part of the signal path of a power amplifier.

10. The electronic circuit as set forth in claim 9 wherein said power amplifier is comprises a linear amplifier.

11. The electronic circuit as set forth in claim 9 wherein said power amplifier is a switching, or Class D amplifier.

12. The electronic circuit as set forth in claim 9 wherein said power amplifier is a tracking, or Class H amplifier.

13. An electronic circuit for processing an audio signal for introducing predictable and controllable harmonic distortion that increases with increasing signal amplitude, said electronic circuit comprising an input buffer, an output buffer, a constant current source, and a non-linear element.

14. The electronic circuit of claim 13 wherein said non-linear element comprises semiconductors.

15. The electronic circuit of claim 14 wherein said semiconductors comprise a progressively biased diode string.

16. The electronic circuit of claim 13 wherein the audio signal is AC-coupled at both ends of the non linear element and is forward-biased by said constant current source.

17. The electronic circuit of claim 13 wherein said constant current source comprises a ring source.

18. The electronic circuit of claim 13 wherein said constant current source comprises a Widlar current mirror.

19. The electronic circuit of claim 13 wherein the quantity of harmonic distortion generated by said circuit is adjustable by varying the bias current from said constant current source.

20. The electronic circuit of claim 15 further comprising an input buffer AC-coupled to the input of said diode string.

21. The electronic circuit of claim 20 wherein said input buffer is AC-coupled to the input of said diode string with a coupling capacitor of sufficient value to substantially prevent restriction of low frequencies due to the input impedance of the diode string.

22. The electronic circuit of claim 15 further comprising an output buffer.

23. The electronic circuit of claim 22 wherein said output buffer comprises a MOSFET source-follower DC-coupled to the output of said diode string.

24. The electronic circuit of claim 15 wherein said diode string comprises a plurality of diodes connected in series having a bias resistor formed at each junction in the series connected to the ground.

25. The electronic circuit of claim 24 wherein the values of said resistors are of a logarithmic sequence with higher values toward the input end of said diode string.

26. The electronic circuit of claim 15 wherein said diodes are implemented as base-emitter junctions of NPN bipolar transistors.

27. The electronic circuit of claim 13 wherein said electronic circuit is maintained at a substantially constant temperature during operation.
